(19) United States
(12) Patent Application Publication
(10) Pub. No.: US 2011/0177671 A1
(43) Pub. Date: Jul. 21, 2011

(54) METHODS OF FORMING A SEMICONDUCTOR CELL ARRAY REGION, METHOD OF FORMING A SEMICONDUCTOR DEVICE INCLUDING THE SEMICONDUCTOR CELL ARRAY REGION, AND METHOD OF FORMING A SEMICONDUCTOR MODULE INCLUDING THE SEMICONDUCTOR DEVICE

(76) Inventors: Sung-Woo HYUN, Seoul (KR); Byeong-Chan LEE, Yongin-si (KR); Sun-Ghil LEE, Hwaseong-si (KR); Yong-Hoon SON, Yongin-si (KR)

(21) Appl. No.: 12/958,858

(22) Filed: Dec. 2, 2010

(30) Foreign Application Priority Data
Jan. 15, 2010 (KR) 10-2010-0003813

(51) Int. Cl. H01L 21/762

(52) U.S. Cl. 438/424; 257/E21.545

(57) ABSTRACT

Methods of forming a semiconductor cell array region, a method of forming a semiconductor device including the semiconductor cell array region, and a method of forming a semiconductor module including the semiconductor device are provided, the methods of forming the semiconductor cell array region include preparing a semiconductor plate. A semiconductor layer may be formed over the semiconductor plate. The semiconductor layer may be etched to form semiconductor pillars over the semiconductor plate.

### PRIORITY STATEMENT

This application claims the benefit of priority under 35 U.S.C. §119 from Korean Patent Application No. 10-2010-0003813, filed on Jan. 15, 2010, the contents of which are hereby incorporated herein by reference in its entirety.

### BACKGROUND

1. Field

Example embodiments relate to methods of forming a semiconductor cell array region, a method of forming a semiconductor device including the semiconductor cell array region, and a method of forming a semiconductor module including the semiconductor device.

2. Description of Related Art

Recently, a semiconductor device has been fabricated with highly-integrated structures due to a reduction of the design rule. One of the structures may be related to a transistor. The transistor may have a three-dimensional active region in a cell array region of the semiconductor device. In this case, the active region may be formed on a semiconductor substrate to be molded in a contact hole of an insulating layer located on the semiconductor substrate. To this end, the active region may be formed through a selective epitaxial process using the semiconductor substrate exposed through the contact hole of the insulating layer as a seed.

Alternatively, the active region may be formed by heating amorphous, or polycrystalline, polysilicon for filling the contact hole of the insulating layer in order to recrystallize the amorphous, or polycrystalline, polysilicon. However, the active region may be isolated from the semiconductor substrate due to a process by-product in the contact hole and/or a diameter of the contact hole. The process by-product in the contact hole may be native oxide between the semiconductor substrate and the active region, and/or a polymer of an etching process gas. The diameter of the contact hole may be related to a gap fill property of the amorphous, or polycrystalline, polysilicon.

The amorphous, or polycrystalline, polysilicon may form a void in the contact hole due to the reduction of the design rule. Accordingly, the transistor may deteriorate the electrical property of the semiconductor device through the active region. The semiconductor device may be disposed in a semiconductor module and/or a process based system. The semiconductor module and/or the process based system may have a poor electrical property due to the semiconductor device.

### SUMMARY

Example embodiments relate to methods of forming a semiconductor cell array region, a method of forming a semiconductor device including the semiconductor cell array region, and a method of forming a semiconductor module including the semiconductor device.

Example embodiments provide a method of forming a semiconductor cell array region that is capable of decreasing effects of a semiconductor fabrication process on an interface between an active region and a semiconductor substrate.

Example embodiments provide a method of forming a semiconductor device and a semiconductor module including a semiconductor cell array region with an active region that is stably secured from a semiconductor substrate.

Example embodiments provide methods of forming a semiconductor cell array region, a semiconductor device and a semiconductor module that are capable of stably securing an active region from a semiconductor plate by forming a semiconductor layer that covers an entire surface of the semiconductor plate.

An example embodiment is directed to a method of forming a semiconductor cell array region, the method may include preparing a semiconductor plate. A semiconductor layer may be formed on the semiconductor plate. The semiconductor layer may be patterned into a plurality of pieces. The plurality of pieces may be insulated from one another on the semiconductor plate to form insulated semiconductor pillars over the semiconductor plate. The semiconductor plate may have a different material than the semiconductor layer. The semiconductor plate and the semiconductor layer may not include oxygen atoms.

In example embodiments, the patterning the semiconductor layer into the plurality of pieces step, and the forming the insulated semiconductor pillars over the semiconductor plate step, may collectively include forming a plurality of photoresist patterns on the semiconductor layer. The photoresist patterns may overlap with the semiconductor pillars, respectively. The semiconductor layer may be etched using the photoresist patterns as an etching mask to form the semiconductor pillars on the semiconductor plate. The photoresist patterns may be removed from the semiconductor plate. An insulating pattern may be formed between the semiconductor pillars. The insulating pattern may include oxygen atoms.

In example embodiments, the patterning the semiconductor layer into the plurality of pieces step, and the forming the insulated semiconductor pillars over the semiconductor plate step, may collectively include forming first photoresist patterns on the semiconductor layer. The first photoresist patterns may each be linear. The semiconductor layer may be etched using the first photoresist patterns as an etching mask to form semiconductor lines on the semiconductor plate. The first photoresist patterns may be removed from the semiconductor plate. First preliminary insulating patterns may be formed between the semiconductor lines. Second photoresist patterns may be formed on the semiconductor lines and the first preliminary insulating patterns.

The second photoresist patterns may each be linear. The second photoresist patterns may intersect with the semiconductor lines and the first preliminary insulating patterns. The semiconductor lines and the first preliminary insulating patterns may be etched using the second photoresist patterns as an etching mask to form the semiconductor pillars and first insulating patterns on the semiconductor plate. The second photoresist patterns may be removed from the semiconductor plate. Second insulating patterns may be formed between the semiconductor pillars and the first insulating patterns. The first and second insulating patterns may include oxygen atoms.

In example embodiments, the semiconductor layer may include at least one first buried pattern. The at least one first buried pattern may be formed along a straight line that connects selected pillars of the semiconductor pillars. The first buried pattern may not include oxygen atoms and may include a different material than the semiconductor plate and the semiconductor layer. The patterning the semiconductor layer into the plurality of pieces step, and the forming the insulated semiconductor pillars over the semiconductor plate step, may collectively include forming first photoresist patterns on the semiconductor layer and the at least one first buried pattern. The first photoresist patterns may each be linear and intersect with the at least one first buried pattern.

The semiconductor layer and the at least one first buried pattern may be etched using the first photoresist patterns as an etching mask to form semiconductor lines on the semiconductor plate. The semiconductor lines may include second buried patterns divided from the at least one first buried pattern, respectively. The first photoresist patterns may be removed from the semiconductor plate. First preliminary insulating patterns may be formed between the semiconductor lines. Second photoresist patterns may be formed on the semiconductor lines and the first preliminary insulating patterns. The second photoresist patterns may each be linear. At least one of the second photoresist patterns may overlap with the second buried patterns. The second photoresist patterns may be located in parallel with the second buried patterns.

The semiconductor lines and the first preliminary insulating patterns may be etched using the second photoresist patterns as an etching mask to form the semiconductor pillars and first insulating patterns on the semiconductor plate. The selected pillars may correspond to third buried patterns divided from the second buried patterns, respectively. The second photoresist patterns may be removed from the semiconductor plate. Second insulating patterns may be formed between the semiconductor pillars and the first insulating patterns. The first and second insulating patterns include oxygen atoms.

In other example embodiments, the method may further include recrystallizing the semiconductor pillars by irradiating the semiconductor pillars with a laser using the semiconductor plate as a seed.

Another example embodiment is directed to a method of forming a semiconductor device. The method may include preparing a semiconductor plate. A semiconductor layer may be formed on a semiconductor plate. The semiconductor layer may include one selected from the group consisting of single-crystalline silicon, poly-crystalline silicon, amorphous silicon, gallium arsenide (GaAs), gallium nitride (GaN), gallium phosphide (GaP), indium phosphide (InP), silicon-germanium (Si—Ge), and a combination thereof. The semiconductor layer may be patterned into a plurality of pieces. The plurality of pieces may be insulated from one another on the semiconductor plate to form insulated semiconductor pillars on the semiconductor plate. The semiconductor plate may include a different material than the semiconductor layer, and may not have oxygen atoms.

In example embodiments, the patterning the semiconductor layer into the plurality of pieces step, and the forming the insulated semiconductor pillars over the semiconductor plate step, may collectively include forming photoresist patterns on the semiconductor layer. The photoresist patterns may overlap with the semiconductor pillars, respectively. The semiconductor layer may be etched using the photoresist patterns as an etching mask to form the semiconductor pillars on the semiconductor plate. The photoresist patterns may be removed from the semiconductor plate. An insulating pattern may be formed between the semiconductor pillars.

In example embodiments, the semiconductor plate may include one selected from the group consisting of single-crystalline silicon, poly-crystalline silicon, amorphous silicon, GaAs, GaN, GaP, InP, Si—Ge, and a combination thereof. The insulating pattern may include oxygen atoms.

In example embodiments, the patterning of the semiconductor layer into the plurality of pieces step, and the forming the insulated semiconductor pillars over the semiconductor plate step, may collectively include forming first photoresist patterns on the semiconductor layer. The first photoresist patterns may each be linear. The semiconductor layer may be etched using the first photoresist patterns as an etching mask to form semiconductor lines on the semiconductor plate. The first photoresist patterns may be removed from the semiconductor plate. First preliminary insulating patterns may be formed between the semiconductor lines.

Second photoresist patterns may be formed on the semiconductor lines and the first preliminary insulating patterns. The second photoresist patterns may each be linear and may intersect with the semiconductor lines and the first preliminary insulating patterns. The semiconductor lines and the first preliminary insulating patterns may be etched using the second photoresist patterns as an etching mask to form the semiconductor pillars and first insulating patterns on the semiconductor plate. The second photoresist patterns may be removed from the semiconductor plate. Second insulating patterns may be formed between the semiconductor pillars and the first insulating patterns.

In example embodiments, the semiconductor plate may include one selected from the group consisting of single-crystalline silicon, poly-crystalline silicon, amorphous silicon, GaAs, GaN, GaP, InP, Si—Ge, and a combination thereof. The first and second insulating patterns may include oxygen atoms.

In example embodiments, the semiconductor layer may include at least one first buried pattern. The at least one first buried pattern may be formed along a straight line that connects selected pillars of the semiconductor pillars. The patterning the semiconductor layer into the plurality of pieces step, and the forming the insulated semiconductor pillars over the semiconductor plate step, may collectively include forming the first photoresist patterns on the semiconductor layer and the at least one first buried pattern. The first photoresist patterns may each be linear and intersect with the at least one first buried pattern. The semiconductor layer and the at least one first buried pattern may be etched using the first photoresist patterns as an etching mask to form semiconductor lines on the semiconductor plate. The semiconductor lines may include second buried patterns divided from the first buried pattern, respectively.

The first photoresist patterns may be removed from the semiconductor plate. First preliminary insulating patterns may be formed between the semiconductor lines. Second photoresist patterns may be formed on the semiconductor lines and the first preliminary insulating patterns. The second photoresist patterns may each be linear. At least one of the second photoresist patterns may overlap with the second buried patterns. The second photoresist patterns may be located in parallel with the second buried patterns. The semiconductor lines and the first preliminary insulating patterns may be etched using the second photoresist patterns as an etching mask to form the semiconductor pillars and first insulating patterns on the semiconductor plate. The selected pillars may correspond to third buried patterns divided from the second buried patterns, respectively. The second photoresist patterns may be removed from the semiconductor plate. Second insulating patterns may be formed between the semiconductor pillars and the first insulating patterns.

In example embodiments, each of the semiconductor plate and the at least one first buried pattern may include one selected from the group consisting of single-crystalline silicon, poly-crystalline silicon, amorphous silicon, GaAs, GaN, GaP, InP, Si—Ge, and a combination thereof. The at least one first buried pattern may include a different material than the semiconductor plate and the semiconductor layer. The first and second insulating patterns may include oxygen atoms.

In example embodiments, the semiconductor layer may include at least one fourth buried pattern intersecting with the at least one first buried pattern. At least one of the first photoresist patterns overlaps with the at least one fourth buried pattern. The first photoresist patterns may be located in parallel with the fourth buried pattern. The at least one fourth buried pattern may be formed as a fifth buried pattern constituting at least one of the semiconductor lines after the etching of the semiconductor layer and the at least one first buried pattern. The fifth buried pattern may be formed as sixth buried patterns underneath the second photoresist patterns after the etching of the semiconductor lines and the first preliminary insulating patterns.

In example embodiments, the first buried pattern may have a greater width than the second photoresist patterns. The fourth buried pattern may have a greater width than the first photoresist patterns.

In example embodiments, the method may further include recrystallizing the semiconductor pillars by irradiating the semiconductor pillars with a laser using the semiconductor plate as a seed.

Still yet another example embodiment is directed to a method of forming a semiconductor module. The method may include preparing a module substrate. At least one semiconductor package structure may be formed to be electrically connected to the module substrate. The at least one semiconductor package structure may have at least one semiconductor device. The at least one semiconductor device may have at least one semiconductor cell array region on a semiconductor plate. The at least one semiconductor cell array region is formed by forming a semiconductor layer on the semiconductor plate, patterning the semiconductor layer into a plurality of pieces; and insulating the plurality of pieces from one another on the semiconductor plate to form insulated semiconductor pillars on the semiconductor plate. The semiconductor plate may have a different material than the semiconductor layer. The semiconductor plate and the semiconductor layer may not include oxygen atoms.

In example embodiments, the patterning of the semiconductor layer into the plurality of pieces step, and the forming the insulated semiconductor pillars over the semiconductor plate step, may collectively include forming photoresist patterns on the semiconductor layer. The photoresist patterns may overlap with the semiconductor pillars, respectively. The semiconductor layer may be etched using the photoresist patterns as an etching mask to form the semiconductor pillars on the semiconductor plate. The photoresist patterns may be removed from the semiconductor plate. An insulating pattern may be formed between the semiconductor pillars. The insulating pattern may include oxygen atoms.

In example embodiments, the patterning the semiconductor layer into the plurality of pieces step, and the forming the insulated semiconductor pillars over the semiconductor plate step, may collectively include forming first photoresist patterns on the semiconductor layer. The first photoresist patterns may each be linear. The semiconductor layer may be etched using the first photoresist patterns as an etching mask to form semiconductor lines on the semiconductor plate. The first photoresist patterns may be removed from the semiconductor plate. First preliminary insulating patterns may be formed between the semiconductor lines.

Second photoresist patterns may be formed on the semiconductor lines and the first preliminary insulating patterns. The second photoresist patterns may each be linear and intersect with the semiconductor lines and the first preliminary insulating patterns. The semiconductor lines and the first preliminary insulating patterns may be etched using the second photoresist patterns as an etching mask to form the semiconductor pillars and first insulating patterns on the semiconductor plate. The second photoresist patterns may be removed from the semiconductor plate. Second insulating patterns may be formed between the semiconductor pillars and the first insulating patterns. The first and second insulating patterns may include oxygen atoms.

In example embodiments, the semiconductor layer may include at least one first buried pattern. The at least one first buried pattern may be formed along a straight line that connects selected pillars of the semiconductor pillars. The at least one first buried pattern may not include oxygen atoms and may include a different material than the semiconductor plate and the semiconductor layer. The patterning the semiconductor layer into the plurality of pieces step, and the forming the insulated semiconductor pillars over the semiconductor plate step, may collectively include forming the first photoresist patterns on the semiconductor layer and the at least one first buried pattern. The first photoresist patterns may each be linear and intersect with the at least one first buried pattern. The semiconductor layer and the at least one first buried pattern may be etched using the first photoresist patterns as an etching mask to form semiconductor lines on the semiconductor plate.

The semiconductor lines may include second buried patterns divided from the at least one first buried pattern, respectively. The first photoresist patterns may be removed from the semiconductor plate. First preliminary insulating patterns may be formed between the semiconductor lines. Second photoresist patterns may be formed on the semiconductor lines and the first preliminary insulating patterns. The second photoresist patterns may each be linear. At least one of the second photoresist patterns may overlap with the second buried patterns. The second photoresist patterns may be located in parallel with the second buried patterns. The semiconductor lines and the first preliminary insulating patterns may be etched using the second photoresist patterns as an etching mask to form the semiconductor pillars and first insulating patterns on the semiconductor plate. The selected pillars may correspond to a plurality of third buried patterns divided from the second buried patterns, respectively. The second photoresist patterns may be removed from the semiconductor plate. Second insulating patterns may be formed between the semiconductor pillars and the first insulating patterns. The first and second insulating patterns may include oxygen atoms.

In other example embodiments, the method may further include recrystallizing the semiconductor pillars by irradiating the semiconductor pillars with a laser using the semiconductor plate as a seed.

According to still another example embodiment, there is provided a method of forming a semiconductor cell array region including forming a stacked structure including a semiconductor layer over a semiconductor plate. The semiconductor plate and the semiconductor layer are formed of materials that exclude oxygen. The semiconductor plate includes at least one different material than the semiconductor layer. The method further includes forming semiconductor pillars over the semiconductor plate by etching the semiconductor layer into a semiconductor pattern, and insulating the semiconductor pillars from each other.

The forming the semiconductor pillars over the semiconductor plate step and the insulating the semiconductor pillars from each other step, collectively include forming photoresist patterns over the semiconductor layer, the photoresist patterns corresponding to the semiconductor pillars, respectively; etching the semiconductor layer into the semiconductor pattern using the photoresist patterns as an etching mask to form the semiconductor pillars over the semiconductor plate; removing the photoresist patterns from the semiconductor plate; and forming an insulating pattern between the semiconductor pillars. The insulating pattern includes oxygen.

### BRIEF DESCRIPTION OF THE DRAWINGS

Example embodiments are described in further detail below with reference to the accompanying drawings. It should be understood that various aspects of the drawings may have been exaggerated for clarity.

FIG. 1 is a plan view showing a semiconductor cell array region according to an example embodiment;

FIGS. 2 and 3 are cross-sectional views taken along line I-I′ of FIG. 1 illustrating a method of forming a semiconductor cell array region according to another example embodiment;

FIG. 4 is a plan view showing a semiconductor cell array region according to still another example embodiment;

FIGS. 5 to 8 are cross-sectional views taken along lines I-I′ and II-II′ of FIG. 4 illustrating a method of forming a semiconductor cell array region according to still a further example embodiment;

FIG. 9 is a plan view showing a semiconductor cell array region according to yet another example embodiment;

FIGS. 10A to 13B are cross-sectional views taken along lines I-I′ and II-II′ of FIG. 9 illustrating a method of forming a semiconductor cell array region according to a further example embodiment;

FIG. 14 is a plan view illustrating a method of forming a semiconductor module including a semiconductor cell array region of FIG. 3, 8, 13A or 13B in a semiconductor device according to still yet another example embodiment; and

FIG. 15 is a plan view for explaining a method of forming a process based system including a semiconductor cell array region of FIG. 3, 8, 13A or 13B in a semiconductor device according to a further example embodiment.

### DETAILED DESCRIPTION OF THE EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to methods of forming a semiconductor cell array region, a method of forming a semiconductor device including the semiconductor cell array region, and a method of forming a semiconductor module including the semiconductor device.

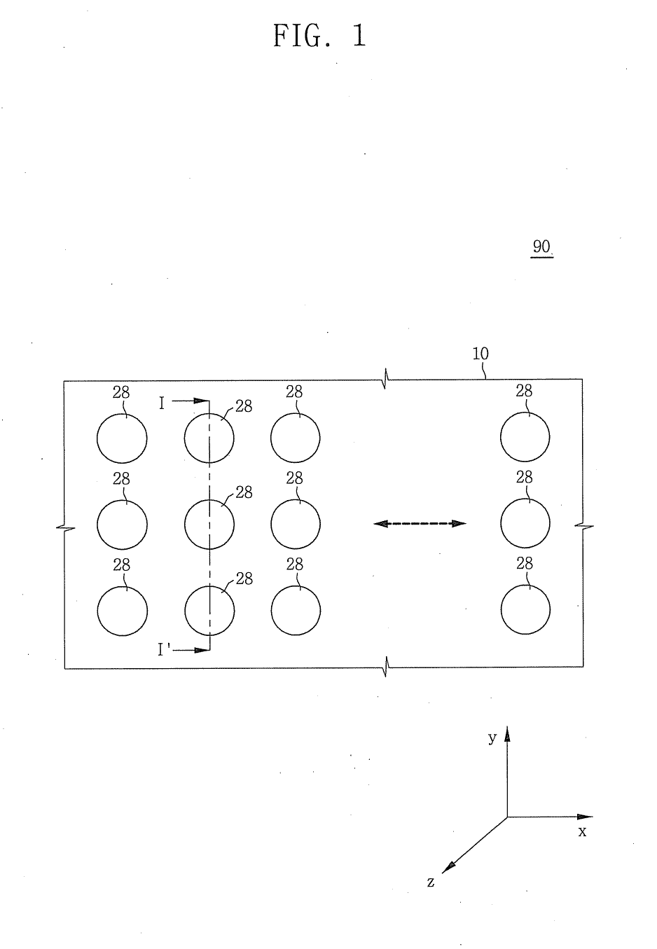

A method of forming a semiconductor cell array region according to an example embodiment will now be described in greater detail with reference to FIGS. 1 to 13.

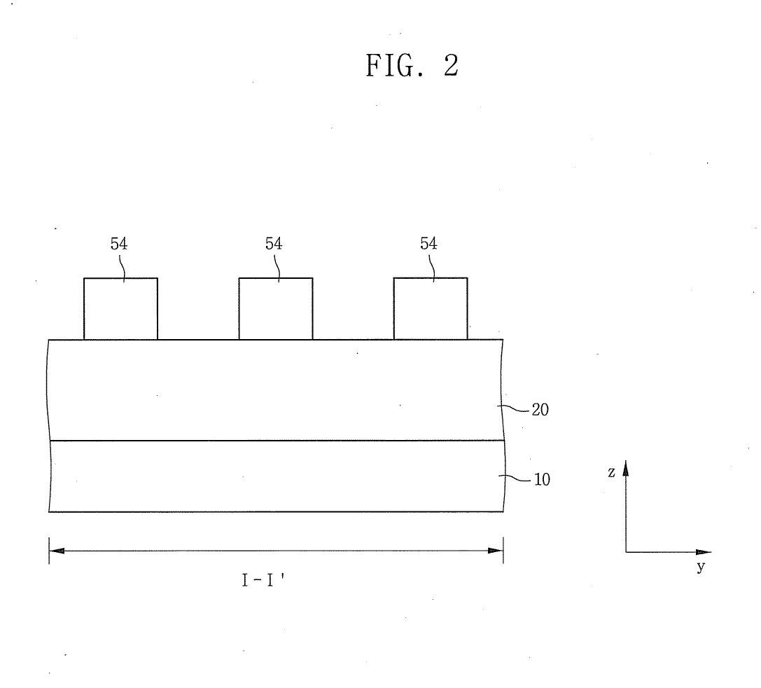

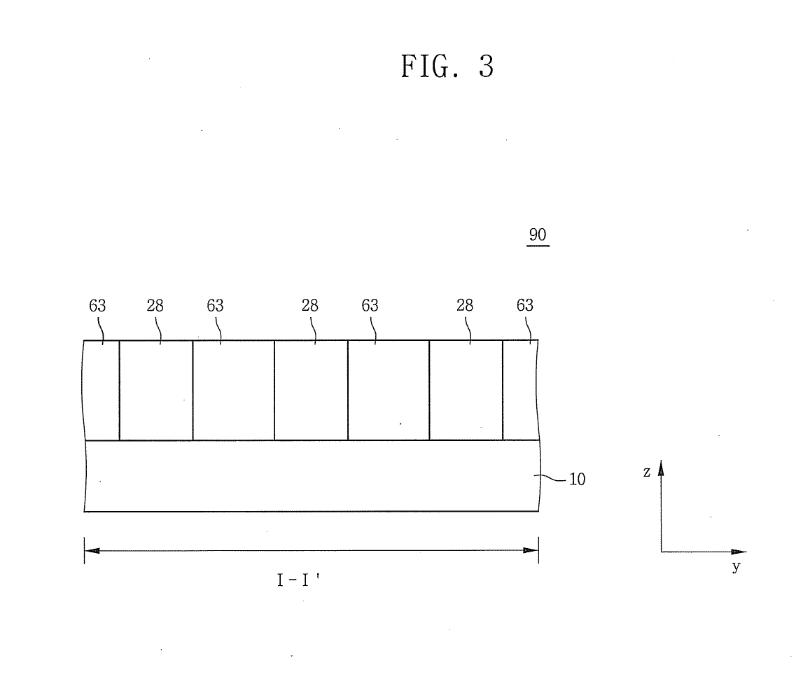

FIG. 1 is a plan view showing a semiconductor cell array region according to an example embodiment. FIGS. 2 and 3 are cross-sectional views taken along line I-I′ of FIG. 1 illustrating a method of forming a semiconductor cell array region according to another example embodiment.

Referring to FIGS. 1 and 2, according to example embodiments, a semiconductor plate 10 may be prepared, as shown in FIG. 2. The semiconductor plate 10 may include one selected from the group consisting of single-crystalline silicon, poly-crystalline silicon, amorphous silicon, gallium arsenide (GaAs), gallium nitride (GaN), gallium phosphide (GaP), indium phosphide (InP), silicon-germanium (Si—Ge), and a combination thereof. Native oxide, organic particles and/or inorganic particles may be removed from an upper surface of the semiconductor plate 10.

A semiconductor layer 20 may be formed on the semiconductor plate 10, as shown in FIG. 2. The semiconductor layer 20 may be formed directly on the semiconductor plate 10. The semiconductor layer 20 may include different material(s) than the semiconductor plate 10. The semiconductor layer 20 may include one selected from the group consisting of single-crystalline silicon, poly-crystalline silicon, amorphous silicon, GaAs, GaN, GaP, InP, Si—Ge, and a combination thereof. Photoresist patterns 54 may be formed on the semiconductor layer 20, as shown in FIG. 2.

In this case, the photoresist patterns 54 may be two-dimensionally formed in X- and Y-axes directions of FIG. 1. The photoresist patterns 54 may overlap with semiconductor pillars 28 of FIG. 1, respectively.

Referring to FIGS. 1 and 3, according to example embodiments, the semiconductor layer 20 may be etched using the photoresist patterns 54 of FIG. 2 as an etching mask to form the semiconductor pillars 28, as shown in FIG. 3. The semiconductor pillars 28 may expose the semiconductor plate 10. The semiconductor pillars 28 may be extended upward from the upper surface of the semiconductor plate 10, i.e., in a Z-axis direction. Accordingly, the semiconductor pillars 28 may be formed in a three-dimensional structure on the semiconductor plate 10.

After the formation of the semiconductor pillars 28 on the semiconductor plate 10, the photoresist patterns 54 may be removed from the semiconductor plate 10. An insulating pattern 63 may be formed between the semiconductor pillars 28, as shown in FIG. 3. The insulating pattern 63 may be located on the semiconductor plate 10 to surround sidewalls of the semiconductor pillars 28. The insulating pattern 63 may isolate the semiconductor pillars 28 in the X-, Y- and Z-axes directions of FIGS. 1 and 3. The insulating pattern 63 may expose upper surfaces of the semiconductor pillars 28.

The insulating pattern 63 may include a material having oxygen atoms. The semiconductor pillars 28 and the insulating pattern 63 may be irradiated with a laser. The semiconductor pillars 28 and the insulating pattern 63 may have different light absorption rates for the laser. In this case, the semiconductor pillars 28 may have a greater light absorption rate than the insulating pattern 63. The laser may melt the semiconductor pillars 28 in a shorter amount of time than the insulating pattern 63.

The laser may be removed (or directed away) from the semiconductor plate 10. The semiconductor pillars 28 may be recrystallized using the semiconductor plate 10 as a seed while being changed from a liquid state to a solid state. Accordingly, the semiconductor pillars 28 may be formed as active regions. The semiconductor pillars 28 may constitute a semiconductor cell array region 90 together with the semiconductor plate 10, as shown in FIG. 3.

The semiconductor cell array region 90 can reduce effects of a semiconductor fabrication process on an interface between the semiconductor plate 10 and the semiconductor layer 20, unlike the conventional art.

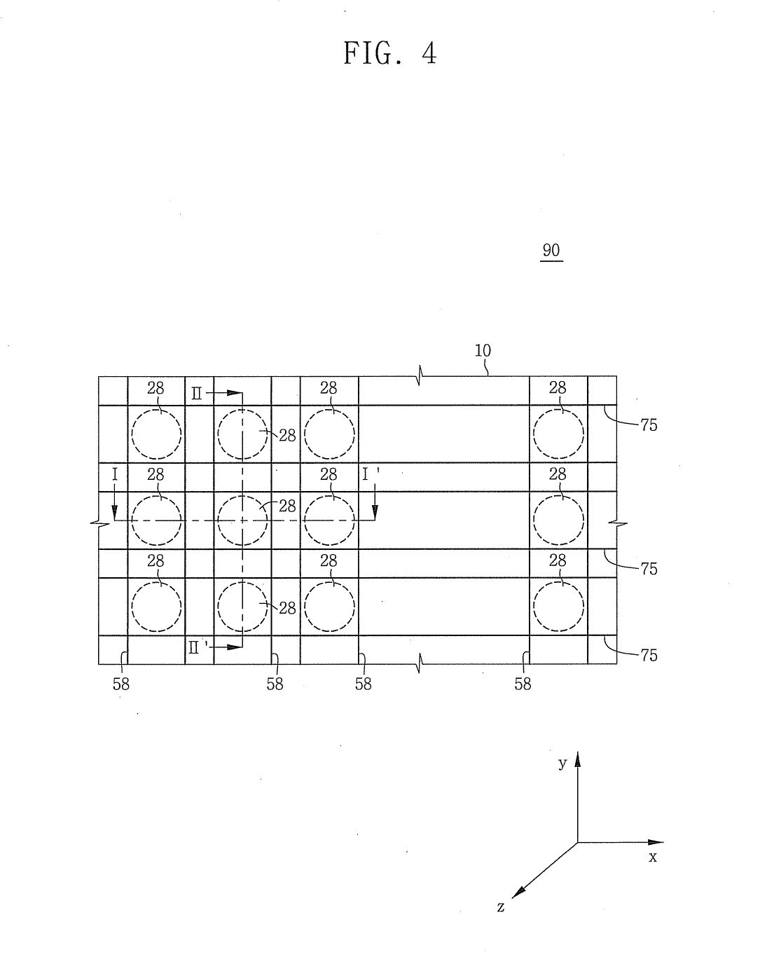

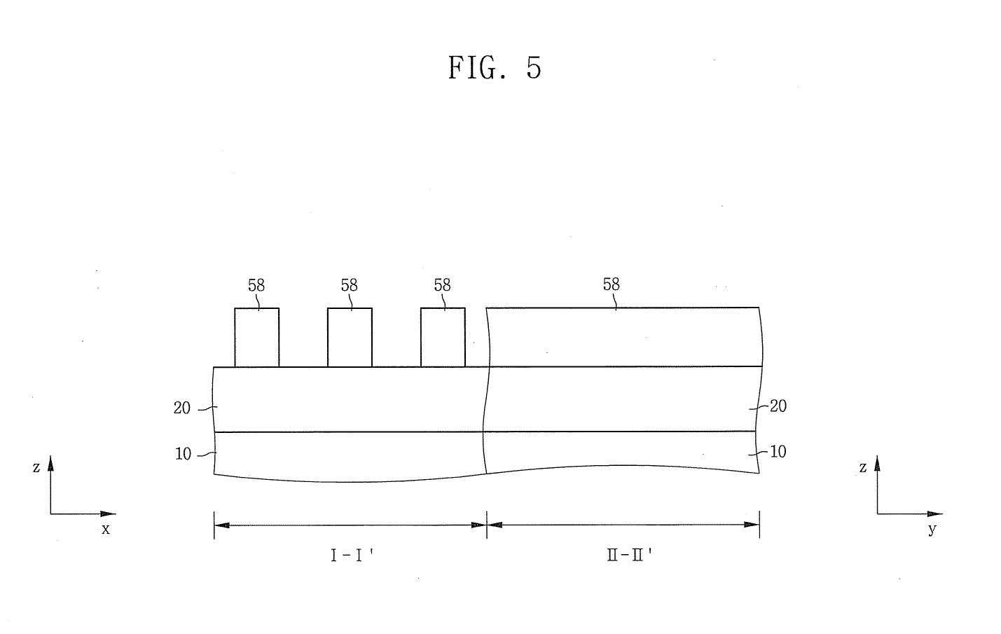

FIG. 4 is a plan view showing a semiconductor cell array region according to still another example embodiment. FIGS. 5 to 8 are cross-sectional views taken along lines I-I′ and II-II′ of FIG. 4 illustrating a method of forming a semiconductor cell array region according to still a further example embodiment.

Here, FIGS. 4 to 8 will use the same reference numeral to those of the same element as FIGS. 1 to 3.

Referring to FIGS. 4 and 5, according to example embodiments, a semiconductor plate 10 may be prepared, as shown in FIG. 5. The semiconductor plate 10 may include one selected from the group consisting of single-crystalline silicon, poly-crystalline silicon, amorphous silicon, GaAs, GaN, GaP, InP, Si—Ge, and a combination thereof. The semiconductor plate 10 may include the same material as, or a different material than that of FIG. 2.

Native oxide, organic particles and/or inorganic particles may be removed from an upper surface of the semiconductor plate 10. A semiconductor layer 20 may be formed on the semiconductor plate 10, as shown in FIG. 5. The semiconductor layer 20 may include a different material from the semiconductor plate 10. The semiconductor layer 20 may include one selected from the group consisting of single-crystalline silicon, poly-crystalline silicon, amorphous silicon, GaAs, GaN, GaP, InP, Si—Ge, and a combination thereof.

First photoresist patterns 58 may be formed on the semiconductor layer 20, as shown in FIGS. 4 and 5. The first photoresist patterns 58 may be formed in a line shape (or each be linear) and located in parallel with one another on the semiconductor layer 20, as shown in FIG. 4. Each of the first photoresist patterns 58 may be formed in a Y-axis direction along a straight line that connects selected pillars of the semiconductor pillars 28 of FIG. 4.

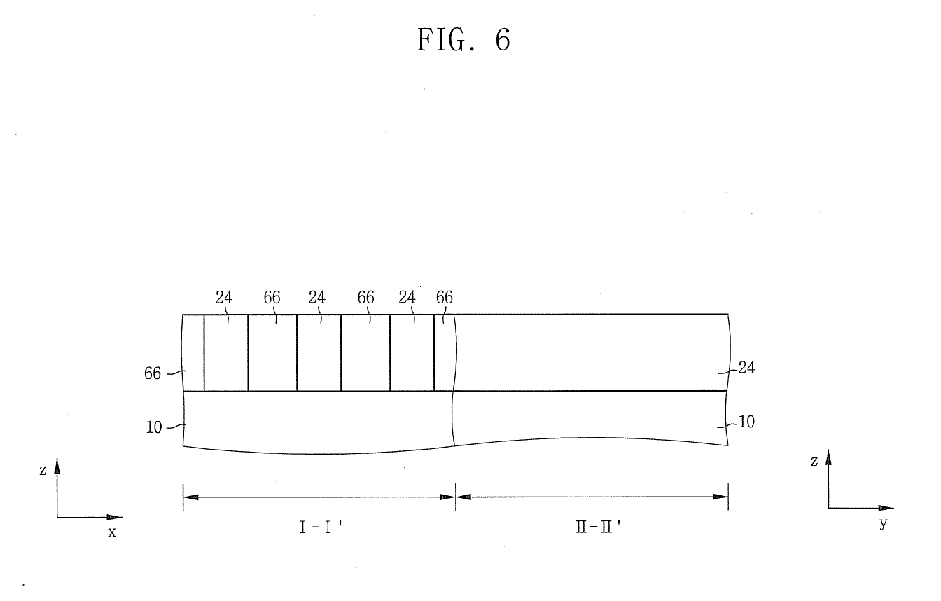

Referring to FIGS. 4 and 6, according to example embodiments, the semiconductor layer 20 may be etched using the first photoresist patterns 58 of FIG. 5 as an etching mask to form semiconductor lines 24, as shown in FIG. 6. The semiconductor lines 24 may expose the semiconductor plate 10. The semiconductor lines 24 may be formed beneath the photoresist patterns 58 of FIG. 4. The semiconductor lines 24 may extend upward from the upper surface of the semiconductor plate 10, i.e., in a Z-axis direction.

After the formation of the semiconductor lines 24 on the semiconductor plate 10, the photoresist patterns 58 may be removed from the semiconductor plate 10. First preliminary insulating patterns 66 may be formed between the semiconductor lines 24. The first preliminary insulating patterns 66 may be formed in a Y-axis direction of FIG. 4. Sidewalls of the semiconductor lines 24 may be covered with the first preliminary insulating patterns 66. The first preliminary insulating patterns 66 may expose upper surfaces of the semiconductor lines 24. The first preliminary insulating patterns 66 may include a material having oxygen atoms.

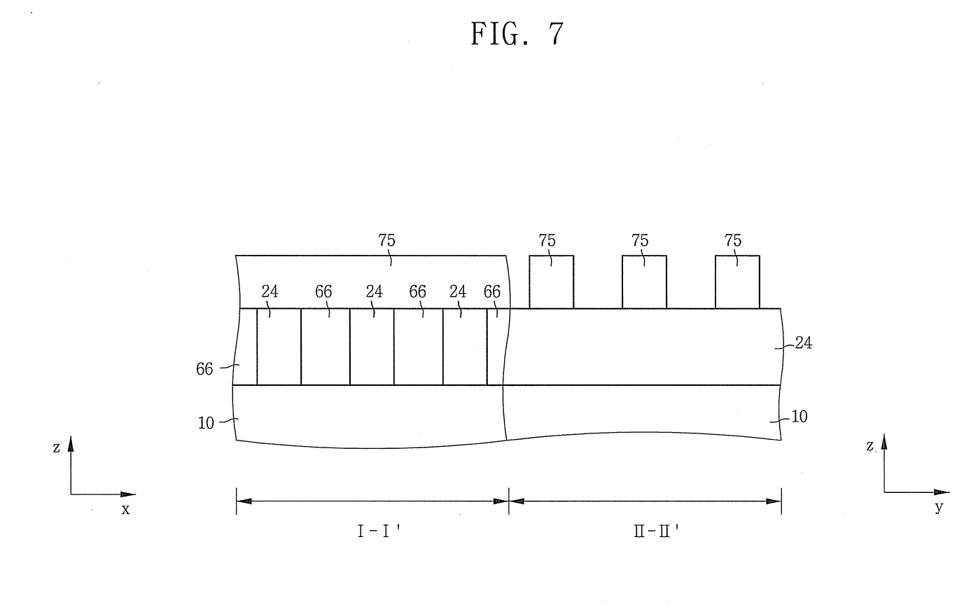

According to example embodiments, second photoresist patterns 75 may be formed on the semiconductor lines 24 and the first preliminary insulating patterns 66, as shown in FIGS. 4 and 7. The second photoresist patterns 75 may be formed in a line shape (or each be linear) and located in parallel with one another on the semiconductor plate 10, as shown in FIG. 4. Each of the second photoresist patterns 75 may be formed in the X-axis direction along a straight line that connects selected pillars of the semiconductor pillars 28 of FIG. 4.

In this case, the second photoresist patterns 75 may intersect with the first photoresist patterns 58 of FIG. 5, as shown in FIG. 4. The first and second photoresist patterns 58 and 75 may have the semiconductor pillars 28 at cross points thereof. Accordingly, the second photoresist patterns 75 may intersect with the semiconductor lines 24 and the first preliminary insulating patterns 66.

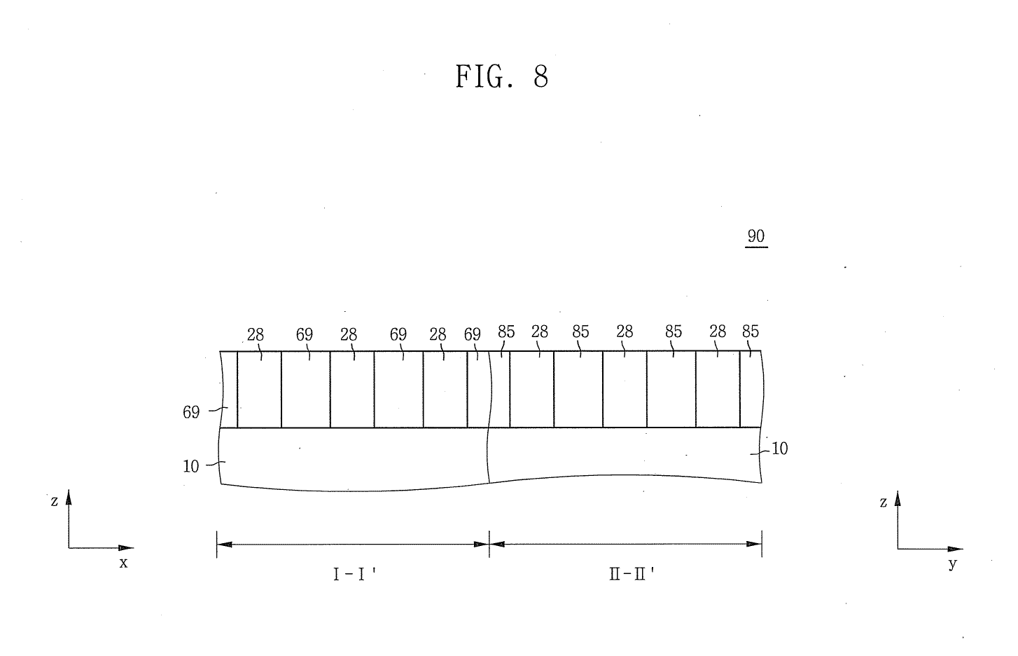

Referring to FIGS. 4 and 8, according to example embodiments, the semiconductor lines 24 and the first preliminary insulating patterns 66 may be etched using the second photoresist patterns 75 of FIG. 7 as an etching mask. The semiconductor lines 24 and the first preliminary insulating patterns 66 may be formed as semiconductor pillars 28 and first insulating patterns 69 beneath the second photoresist patterns 75, as shown in FIG. 8. The semiconductor pillars 28 and the first insulating patterns 69 may expose the semiconductor plate 10.

The semiconductor pillars 28 may extend upward from the upper surface of the semiconductor plate 10, i.e., in a Z-axis direction. Accordingly, the semiconductor pillars 28 may be formed in a three-dimensional structure on the semiconductor plate 10. The first insulating patterns 69 may be formed in an X-axis direction between semiconductor pillars 28. After the formation of the semiconductor pillars 28 and the first insulating patterns 69 on the semiconductor plate 10, the second photoresist patterns 75 may be removed from the semiconductor plate 10.

Second insulating patterns 85 may be formed between the semiconductor pillars 28 and the first insulating patterns 69, as shown in FIG. 8. The second insulating patterns 85 may be formed in the X-axis direction. The second insulating patterns 85 may be located on the semiconductor plate 10 to cover sidewalls of the semiconductor pillars 28 and the first insulating patterns 69. The second insulating patterns 85 may expose the upper surfaces of the semiconductor pillars 28 and the first insulating pattern 69. The second insulating patterns 85 may include a material having oxygen atoms.

The first and second insulating patterns 69 and 85 may isolate the semiconductor pillars 28 in the X-, Y- and Z-axes directions of FIGS. 4 and 8. The semiconductor pillars 28 and the first and second insulating patterns 69 and 85 may be irradiated with a laser. The semiconductor pillars 28 and the first and second insulating patterns 69 and 85 may have different light absorption rates for laser. In this case, the semiconductor pillars 28 may have a greater light absorption rate than the first and second insulating patterns 69 and 85.

The laser may melt the semiconductor pillars 28 in a shorter time than the first and second insulating patterns 69 and 85. The laser may be removed (or directed away) from the semiconductor plate 10. The semiconductor pillars 28 may be recrystallized using the semiconductor plate 10 as a seed while being changed from a liquid state to a solid state. Accordingly, the semiconductor pillars 28 may be formed as active regions. The semiconductor pillars 28 may constitute a semiconductor cell array region 90 together with the semiconductor plate 10, as shown in FIG. 8.

The semiconductor cell array region 90 can reduce effects of a semiconductor fabrication process on an interface between the semiconductor plate 10 and the semiconductor layer 20, unlike the conventional art.

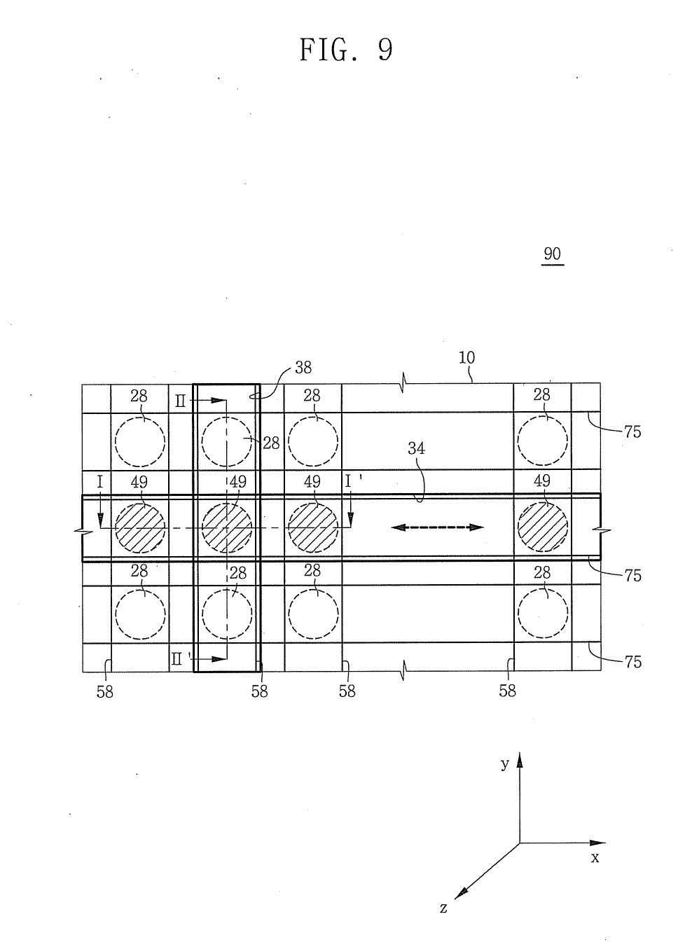

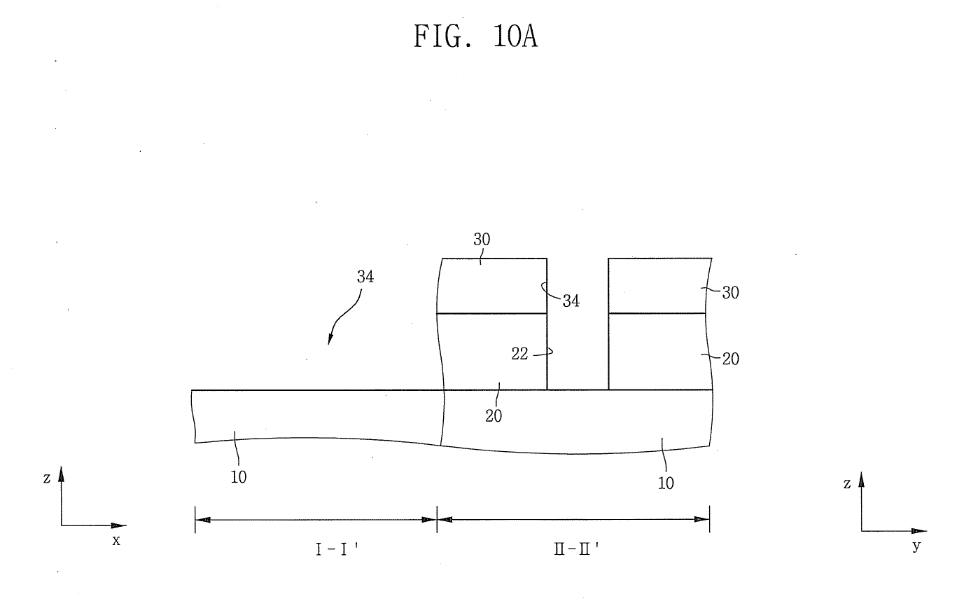

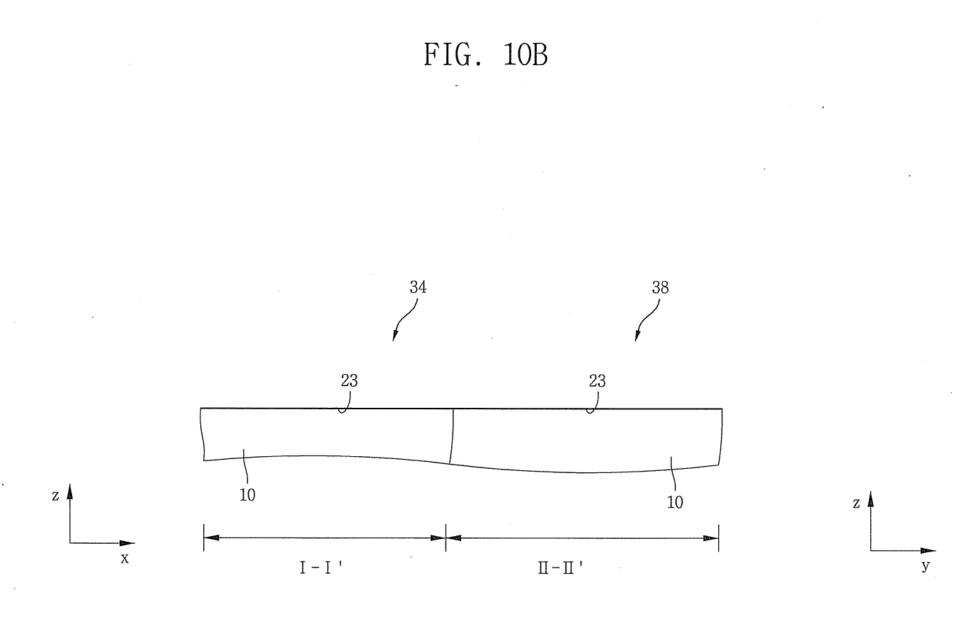

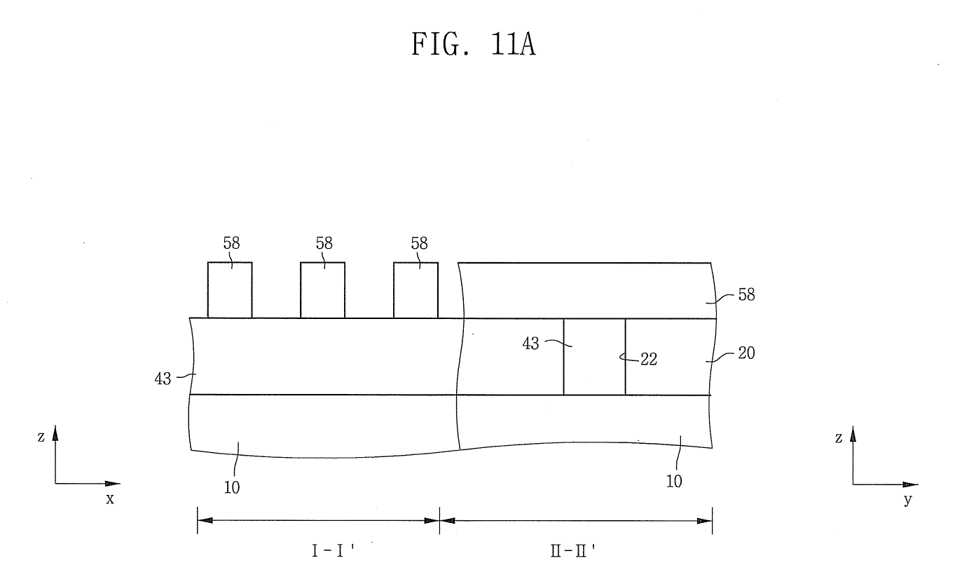

FIG. 9 is a plan view showing a semiconductor cell array region according to yet another example embodiment. FIGS. 10A to 13B are cross-sectional views taken along lines I-I′ and II-II′ of FIG. 9 illustrating a method of forming a semiconductor cell array region according to a further example embodiment.

Here, FIGS. 9 to 13B will use the same reference numeral to those of the same element as FIGS. 4 to 8.

Referring to FIGS. 9 and 10A, according to example embodiments, a semiconductor plate 10 may be prepared, as shown in FIG. 10A. The semiconductor plate 10 may include one selected from the group consisting of single-crystalline silicon, poly-crystalline silicon, amorphous silicon, GaAs, GaN, GaP, InP, Si—Ge, and a combination thereof. The semiconductor plate 10 may include the same material as, or a different material than, that in FIG. 5.

Native oxide, organic particles and/or inorganic particles may be removed from an upper surface of the semiconductor plate 10. A semiconductor layer 20 may be formed on the semiconductor plate 10, as shown in FIG. 10A. The semiconductor layer 20 may include a different material than the semiconductor plate 10. The semiconductor layer 20 may include one selected from the group consisting of single-crystalline silicon, poly-crystalline silicon, amorphous silicon, GaAs, GaN, GaP, InP, Si—Ge, and a combination thereof.

A first photoresist layer 30 may be formed on the semiconductor layer 20, as shown in FIG. 10A. The first photoresist layer 30 may have at least one first opening 34, as shown in FIGS. 9 and 10A. The first opening 34 may be formed in an X-axis direction along a straight line that connects selected pillars of semiconductor pillars 28 of FIG. 9. The first opening 34 may expose the semiconductor layer 20. Subsequently, the semiconductor layer 20 may be etched using the first photoresist layer 30 as an etching mask to form a first through-hole 22 in the semiconductor layer 20.

The first through-hole 22 may be aligned with the first opening 34 to expose the semiconductor plate 10. On the contrary, the first photoresist layer 30 may also have at least one second opening 38 instead of the at least one first opening 34, as shown in FIG. 9. The second opening 38 may be formed in a Y-axis direction along a straight line that connects selected pillars of the semiconductor pillars 28 of FIG. 9. The second opening 38 may intersect with the first opening 34, as shown in FIG. 9. The second opening 38 may expose the semiconductor layer 20.

Referring to FIGS. 9 and 10B, the first photoresist layer 30 may simultaneously have at least one pair of first and second openings 34 and 38, as shown in FIG. 9. When the at least one pair of first and second openings 34 and 38 are formed in the photoresist layer 30, the semiconductor layer 20 may be etched using the photoresist layer 30 as an etching mask to form a second through-hole 23 in the semiconductor layer 20. The second through-hole 23 may be aligned with the at least one pair of first and second openings 34 and 38 to expose the semiconductor plate 10.

In this case, the second through-hole 23 may have a crisscross shape in the X- and Y-axes directions of FIG. 9.

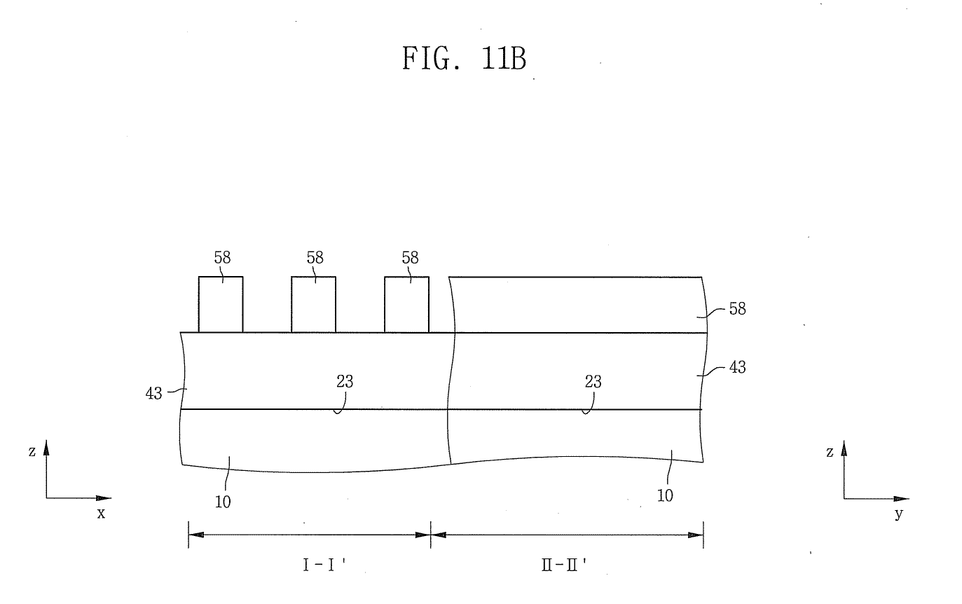

Referring to FIGS. 9 and 11A, according to example embodiments, after the formation of the first through-hole 22 of FIG. 10A in the semiconductor layer 20, the first photoresist layer 30 of FIG. 10A may be removed from the semiconductor layer 20. A first buried pattern 43 may be formed in the first through-hole 22, as shown in FIG. 11A. The first buried pattern 43 may fill the first through-hole 22 while exposing the upper surface of the semiconductor layer 20. Second photoresist patterns 58 may be formed on the semiconductor layer 20 and the first buried pattern 43, as shown in FIGS. 9 and 11A.

The second photoresist patterns 58 may have the same shape and/or structure as that of FIG. 5. In this case, the second photoresist patterns 58 may intersect with the first buried pattern 43.

Referring to FIGS. 9 and 11B, after the formation of the second through-hole 23 discussed in association with FIG. 10B in the semiconductor layer 20, the first photoresist layer 30 of FIG. 10A may be removed from the semiconductor layer 20. The first buried pattern 43 may be formed in the second through-hole 23, as shown in FIG. 11B.

The first buried pattern 43 may fill the second through-hole 23 while exposing the upper surface of the semiconductor layer 20. The second photoresist patterns 58 may be formed on the semiconductor layer 20 and the first buried pattern 43, as shown in FIGS. 9 and 11B. In this case, one of the second photoresist patterns 58 may overlap with and cover a portion of the first buried pattern 43 in the Y-axis direction of FIG. 11B. The remaining second photoresist patterns 58 may intersect with the other portion of the first buried pattern 43 in an X-axis direction of FIGS. 9 and 11B.

The one second photoresist pattern 58 may have a smaller width than the portion of the first buried pattern 43, as shown in FIG. 9. The first buried pattern 43 may include a different material than the semiconductor plate 10 and the semiconductor layer 20. The first buried pattern 43 may include one selected from the group consisting of single-crystalline silicon, poly-crystalline silicon, amorphous silicon, GaAs, GaN, GaP, InP, Si—Ge, and a combination thereof.

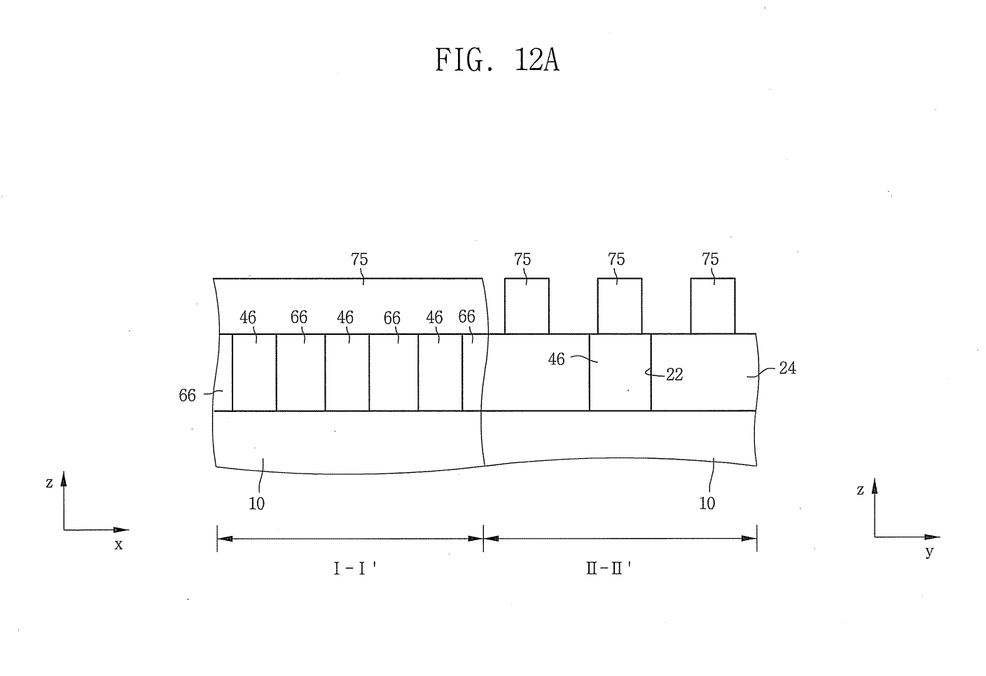

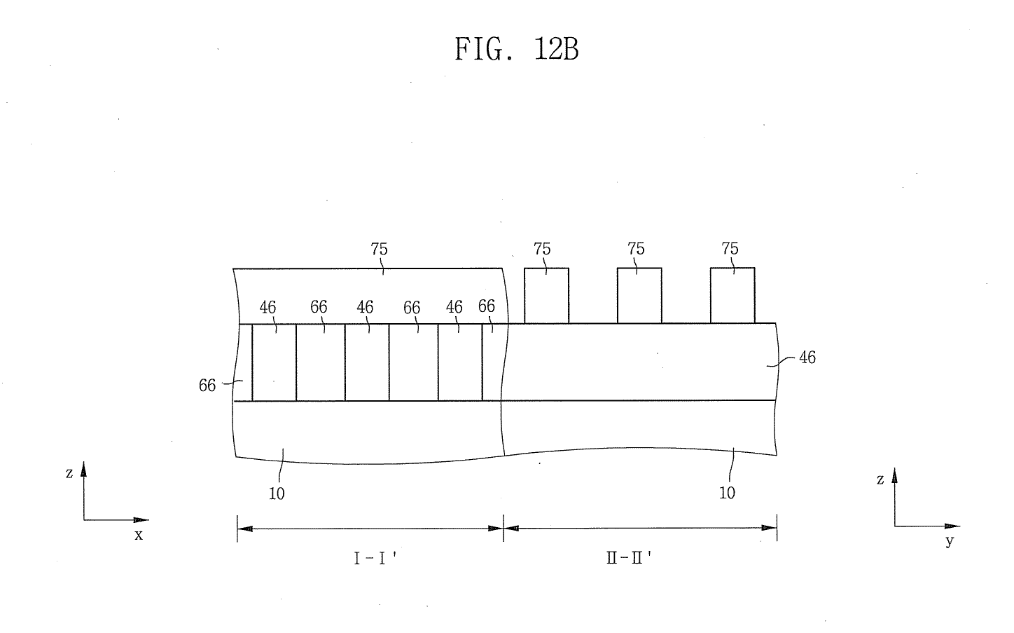

Referring to FIGS. 9 and 12A, according to example embodiments, when the first buried pattern 43 of FIG. 11A is formed in the X-axis direction of FIG. 9, the semiconductor layer 20 and the first buried pattern 43 may be etched using the second photoresist patterns 58 of FIG. 11A as an etching mask. The semiconductor layer 20 may be formed as semiconductor lines 24 in the Y-axis direction of FIG. 9, as shown in FIG. 12A. The first buried pattern 43 may be formed as second buried patterns 46 in the X-axis direction of FIG. 9, as shown in FIG. 12A.

The semiconductor lines 24 may have the second buried patterns 46, respectively. After the formation of the semiconductor lines 24 on the semiconductor plate 10, the second photoresist patterns 58 may be removed from the semiconductor plate 10. Subsequently, first preliminary insulating patterns 66 may be formed between the semiconductor lines 24, as shown in FIG. 12A. The first preliminary insulating patterns 66 may be formed in the X-axis direction of FIG. 9. Sidewalls of the semiconductor lines 24 and the second buried patterns 46 may be covered with the first preliminary insulating patterns 66.

The first preliminary insulating patterns 66 may have the same material as those of FIG. 6. Third photoresist patterns 75 may be formed on the semiconductor lines 24, the second buried patterns 46 and the first preliminary insulating patterns 66, as shown in FIG. 12A. The third photoresist patterns 75 may have the same shape and/or structure as those of FIG. 7. In this case, one of the third photoresist patterns 75 may overlap with the second buried patterns 46 in the X-axis direction of FIG. 9.

The one of the third photoresist patterns 75 may have a smaller width than the second buried patterns 46.

Referring to FIGS. 9 and 12B, when the first buried pattern 43 of FIG. 11B is in the X- and Y-axes directions of FIG. 9, the semiconductor layer 20 and the first buried pattern 43 may be etched using the second photoresist patterns 58 of FIG. 11B as an etching mask. The semiconductor layer 20 may be formed as semiconductor lines 24 in the Y-axis direction of FIG. 9, similarly to FIG. 12A. The first buried pattern 43 may be formed as second buried patterns 46 in the X- and Y-axes directions of FIG. 9, as shown in FIG. 12B. A portion of the first buried pattern 43 may be formed as second selected buried patterns 46 in the X-axis direction of FIG. 9, as shown in FIG. 12B.

The second selected buried patterns 46 may be included in selected parts of the semiconductor lines 24, respectively. The remaining first buried pattern 43 may be formed as the remaining second buried patterns 46 in the Y-axis direction of FIG. 9, as shown in FIG. 12B. The remaining second buried pattern 46 may constitute the remaining part of semiconductor lines 24. After the formation of the semiconductor lines 24 and the second buried patterns 46 on the semiconductor plate 10, the second photoresist patterns 58 may be removed from the semiconductor plate 10.

Subsequently, first preliminary insulating patterns 66 may be formed between the semiconductor lines 24, as shown in FIG. 12B. Sidewalls of the semiconductor lines 24 and the second buried patterns 46 may be covered with the first preliminary insulating patterns 66. Third photoresist patterns 75 may be formed on the semiconductor lines 24, the second buried patterns 46 and the first preliminary insulating patterns 66, as shown in FIG. 12B. In this case, one of the third photoresist patterns 75 may overlap with the second selected buried patterns 46 in the X-axis direction of FIG. 9, as shown in FIG. 12B.

The one of the third photoresist patterns 75 may have a smaller width than the second selected buried patterns 46, as shown in FIG. 9. The remaining third photoresist patterns 75 may intersect with the remaining second buried patterns 46 in the Y-axis direction of FIGS. 9 and 12B.

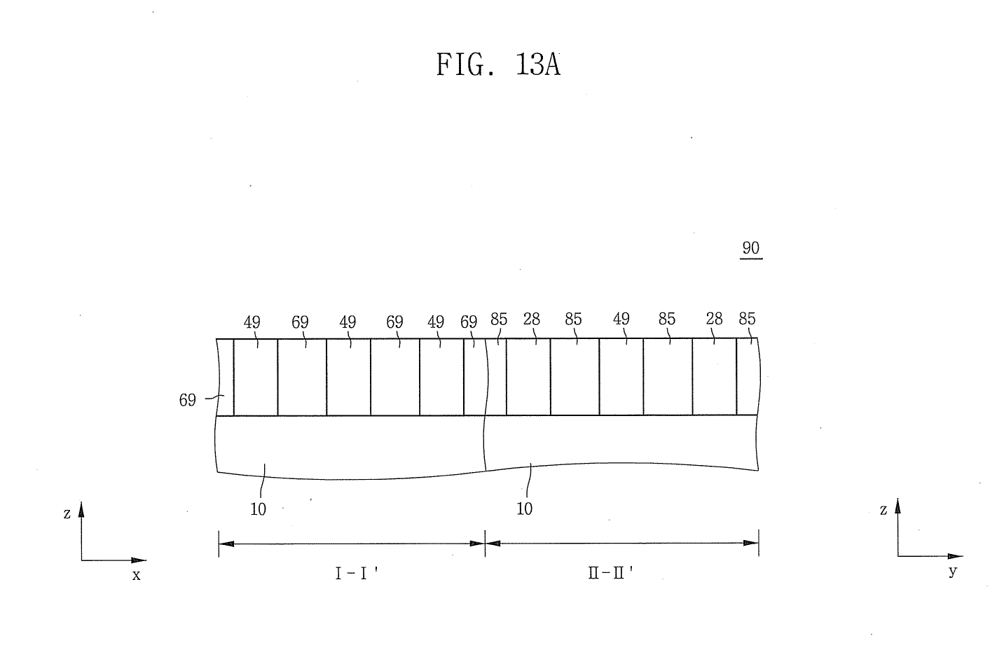

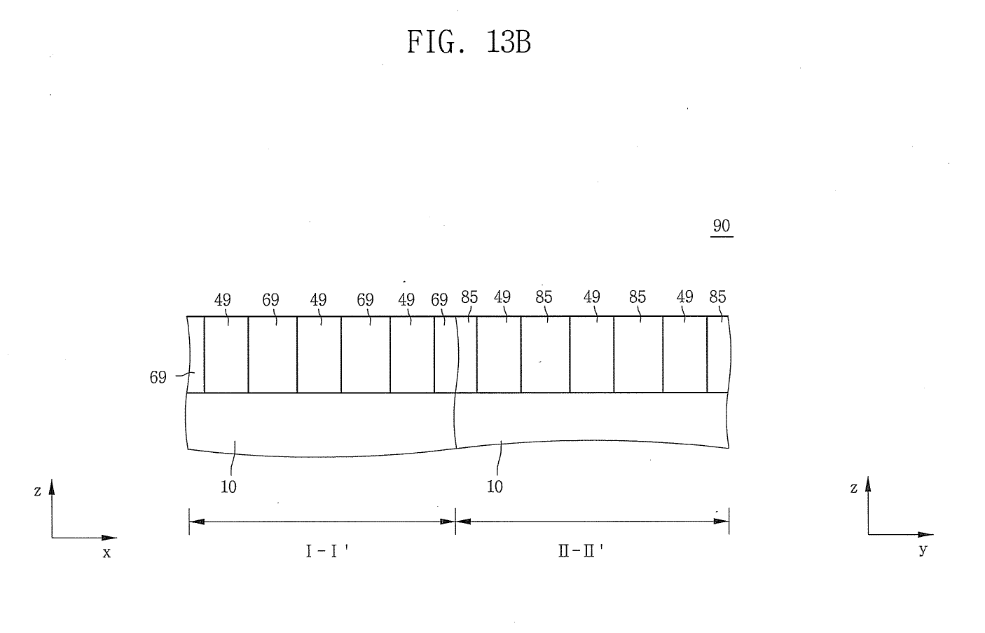

Referring to FIGS. 9 and 13A, according to example embodiments, when the second buried pattern 46 of FIG. 12A is formed in the X-axis direction of FIG. 9, the semiconductor lines 24, the second buried patterns 46 and the first preliminary insulating patterns 66 may be etched using the third photoresist patterns 75 of FIG. 12A as an etching mask. The semiconductor lines 24 and the first preliminary insulating patterns 66 may be formed as semiconductor pillars 28 and first insulating patterns 69 beneath the third photoresist patterns 75, as shown in FIG. 13A.

The semiconductor pillars 28 and the first insulating patterns 69 may expose the semiconductor plate 10. The semiconductor pillars 28 may extend upward from the upper surface of the semiconductor plate 10, i.e., in the Z-axis direction. Accordingly, the semiconductor pillars 28 may be formed in a three-dimensional structure on the semiconductor plate 10. The first insulating patterns 69 may be formed between the semiconductor pillars 28 in the X-axis direction of FIG. 9.

In this case, the second buried patterns 46 of FIG. 12A may be separated from the semiconductor lines 24 and formed as third buried patterns 49. The third buried patterns 49 may act as the semiconductor pillars 28 in the X-axis direction of FIG. 9. After the formation of the semiconductor pillars 28, the third buried patterns 49 and the first insulating patterns 69 on the semiconductor plate 10, the third photoresist patterns 75 may be removed from the semiconductor plate 10. Second insulating patterns 85 may be formed between the semiconductor pillars 28, the third buried patterns 49 and the first insulating patterns 69, as shown in FIG. 13A.

The second insulating patterns 85 may be formed in the X-axis direction of FIG. 9. The second insulating patterns 85 may be located on the semiconductor plate 10 to cover sidewalls of the semiconductor pillars 28, the third buried patterns 49 and the first insulating patterns 69. The second insulating patterns 85 may expose the upper surfaces of the semiconductor pillars 28, the third buried patterns 49 and the first insulating patterns 69. The second insulating patterns 85 may have the same material as those of FIG. 8. The first and second insulating patterns 69 and 85 may isolate the semiconductor pillars 28 and the third buried patterns 49 in the X-, Y- and Z-axes directions of FIGS. 9 and 13A.

Referring to FIGS. 9 and 13B, when the second buried pattern 46 of FIG. 12B is formed in the X- and Y-axes directions of FIG. 9, the semiconductor lines 24, the second buried patterns 46 and the first preliminary insulating patterns 66 may be etched using the third photoresist patterns 75 of FIG. 12B as an etching mask. The semiconductor lines 24 and the first preliminary insulating pattern 66 may be formed as semiconductor pillars 28 and first insulating patterns 69 beneath the second photoresist patterns 75, similarly to FIG. 13A. The semiconductor pillars 28 and the first insulating patterns 69 may expose the semiconductor plate 10.

The semiconductor pillars 28 may extend upward from the upper surface of the semiconductor plate 10, i.e., in the Z-axis direction. Accordingly, the semiconductor pillars 28 may be formed in a three-dimensional structure on the semiconductor plate 10. The first insulating patterns 69 may be formed in the X-axis direction between the semiconductor pillars 28. In this case, the second buried patterns 46 may be formed as third buried patterns 49, as shown in FIG. 13B. That is, the second selected buried patterns 46 of FIG. 12 may be separated from the semiconductor lines 24 of FIG. 12B in the X-axis direction of FIG. 9 and formed as the third selected buried patterns 49.

The remaining second buried patterns 46 of FIG. 12 may be divided in the Y-axis direction of FIG. 9, as shown in FIG. 13B and formed as the remaining third buried patterns 49. The remaining third buried patterns 49 may be formed along the line II-II′ of FIG. 9. The remaining third buried patterns 49 may act as the semiconductor pillars 28 together with the third selected buried patterns 49. After the formation of the semiconductor pillars 28, the third buried patterns 49 and the first insulating patterns 69 on the semiconductor plate 10, the third photoresist patterns 75 may be removed from the semiconductor plate 10.

Second insulating patterns 85 may be formed between the semiconductor pillars 28, the third buried patterns 49 and the first insulating patterns 69. The second insulating patterns 85 may be formed in the X-axis direction of FIG. 9, as shown in FIG. 13B. The second insulating pattern 85 may be located on the semiconductor plate 10 to cover sidewalls of the semiconductor pillars 28, the third buried patterns 49 and the first insulating patterns 69. The second insulating pattern 85 may expose upper surfaces of the semiconductor pillars 28, the third buried patterns 49 and the first insulating patterns 69. The first and second insulating patterns 69 and 85 may isolate the semiconductor pillars 28 and the third buried patterns 49 in the X-, Y- and Z-axes directions of FIGS. 9 and 13B.

The semiconductor pillars 28, the third buried patterns 49 and the first and second insulating patterns 69 and 85 in FIGS. 13A and 13B may be irradiated with a laser. The semiconductor pillars 28, the third buried patterns 49 and the first and second insulating patterns 69 and 85 may have different light absorption rates for the laser. In this case, the semiconductor pillars 28 and the third buried patterns 49 may have a greater light absorption rate than the first and second insulating patterns 69 and 85. The laser may melt the semiconductor pillars 28 and the third buried patterns 49 in a shorter amount of time than the first and insulating patterns 69 and 85.

The laser may be removed from the semiconductor plate 10. The semiconductor pillars 28 and the third buried patterns 49 may be recrystallized using the semiconductor plate 10 as a seed while being changed from a liquid state to a solid state. Accordingly, the semiconductor pillars 28 and the third buried patterns 49 may be formed as active regions. The semiconductor pillars 28 and the third buried patterns 49 may constitute a semiconductor cell array region 90 together with the semiconductor plate 10, as shown in FIGS. 13A and 13B.

The semiconductor cell array region 90 can reduce effects of a semiconductor fabrication process on an interface between the semiconductor plate 10 and the semiconductor layer 20, unlike the conventional art.

A method of forming a semiconductor module and a method of forming a processor-based system according to example embodiments will now be described.

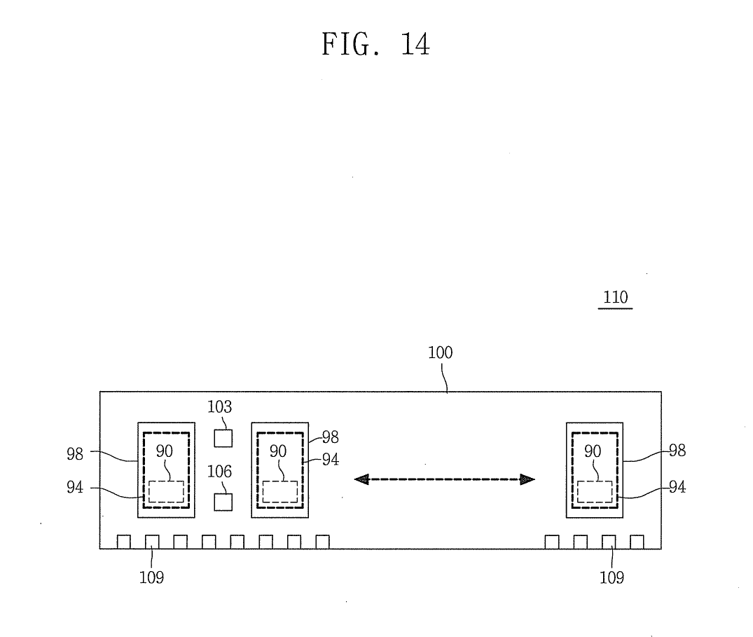

FIG. 14 is a plan view illustrating a method of forming a semiconductor module including a semiconductor cell array region of FIG. 3, 8, 13A or 13B in a semiconductor device according to still yet another example embodiment.

Referring to FIG. 14, according to example embodiments, a module substrate 100 may be prepared. The module substrate 100 may include a printed circuit board. The module substrate 100 may include internal circuits (not shown), electrical pads (not shown), and connectors 109. The internal circuits may be electrically connected to the electrical pads and the connectors 109. Semiconductor package structures 98 and at least one resistor 103 may be formed on the module substrate 100.

The semiconductor package structures 98, the at least one resistor 103, and at least one capacitor 106 may be formed on the module substrate 100. The semiconductor package structures 98, the at least one resistor 103 and/or the at least one capacitor 106 may be electrically connected to the electrical pads. Each of the semiconductor package structures 98 may include at least one semiconductor device 94. The semiconductor device 94 may include the semiconductor cell array region 90 of FIG. 3, 8, 13A or 13B.

The semiconductor cell array region 90 may repeatedly and periodically have the semiconductor pillars 28 along rows and columns of the semiconductor plate 10. Accordingly, the semiconductor cell array region 90 may repeatedly and periodically have transistors corresponding to the semiconductor pillars 28 along the rows and the columns of the semiconductor plate 10. Accordingly, the semiconductor package structures 98 and the at least one resistor 103 may constitute a semiconductor module 110 together with the module substrate 100.

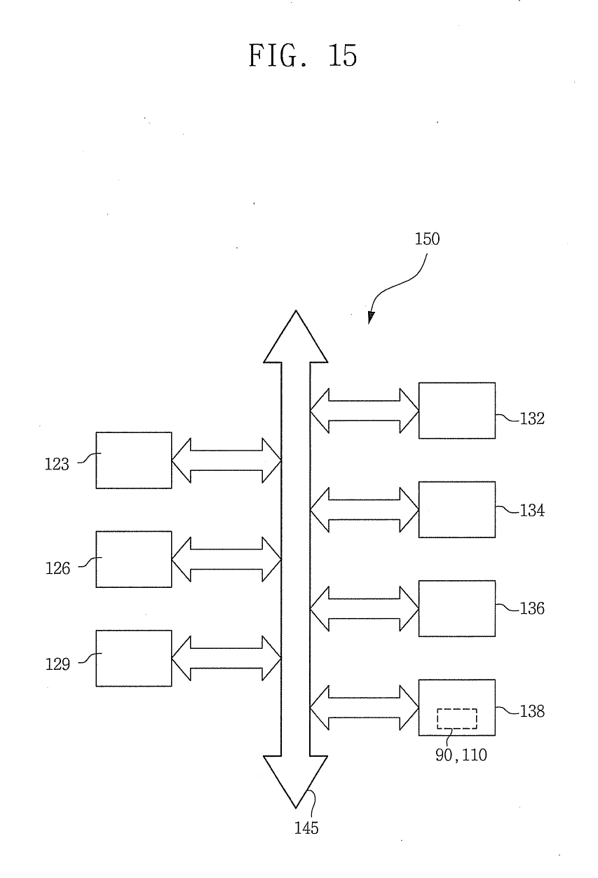

The semiconductor package structures 98, the at least one resistor 103 and the at least one capacitor 106 may also constitute the semiconductor module 110 together with the module substrate 100. The at least one semiconductor device 94 in each of the semiconductor package structures 98 allows the semiconductor module 110 to have an increased electrical property than the conventional art. The semiconductor module 100 may be electrically connected to a processor-based system 150 of FIG. 15 through the connectors 109 of the module substrate 110.

FIG. 15 is a plan view illustrating a method of forming a process based system including a semiconductor cell array region of FIG. 3, 8, 13A or 13B in a semiconductor device according to a further example embodiment.

Referring to FIG. 15, according to example embodiments, at least one system board (not shown) may be prepared. The at least one system board may have at least one bus line 145. A first module unit may be formed on the at least one bus line 145. The first module unit may be electrically connected to the at least one bus line 145.

The first module unit may include a central processing unit (CPU) 123, a floppy disk drive 126, and a compact disk ROM drive 129. In addition, a second module unit may be formed on the at least one bus line 145. The second module unit may be electrically connected to the at least one bus line 145.

The second module unit may include a first input/output (I/O) device 132, a second I/O device 134, a read-only memory (ROM) 136 and a random access memory (RAM) 138. The RAM 138 may include the semiconductor device 94 of FIG. 14. The RAM 138 may include the semiconductor module 110 of FIG. 14.

The ROM 186 may also include the semiconductor cell array region 90 of FIG. 3, 8, 13A or 13B. The first and second module units may constitute the processor-based system 150 according to example embodiments together with the at least one bus line 145. The semiconductor device 94 and/or the semiconductor module 110 allow the processor-based system 150 to have an increased electrical property than the conventional art.

The processor-based system 150 may include a computer system, a process control system, or any other system.

As described above, the example embodiments can provide a semiconductor cell array region that is capable of reducing effects of a semiconductor fabrication process while the semiconductor pillar is being formed on the semiconductor plate. The semiconductor pillar may be related to a transistor on the semiconductor plate. The semiconductor pillar allows the transistor to have an increased electrical property than the conventional art.

The semiconductor cell array region may be included in the semiconductor device. The semiconductor device may include a volatile memory and/or a nonvolatile memory. The semiconductor device may have an increased electrical property compared with the conventional art. In addition, the semiconductor device can be included in the semiconductor module. The semiconductor device allows the semiconductor module to have an increased electrical property than the conventional art.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A method of forming a semiconductor cell array region, comprising:
preparing a semiconductor plate;
forming a semiconductor layer over the semiconductor plate, the semiconductor plate having a different material than the semiconductor layer, and the semiconductor plate and the semiconductor layer formed of materials that exclude oxygen atoms;
patterning the semiconductor layer into a plurality of pieces; and
forming insulated semiconductor pillars over the semiconductor plate.

2. The method of claim 1, wherein the patterning the semiconductor layer into the plurality of pieces step and the forming the insulated semiconductor pillars step, collectively comprise:
forming photoresist patterns over the semiconductor layer, the photoresist patterns overlapping with the semiconductor pillars, respectively;
etching the semiconductor layer using the photoresist patterns as an etching mask to form the semiconductor pillars over the semiconductor plate;
removing the photoresist patterns from the semiconductor plate; and
forming an insulating pattern between the semiconductor pillars, the insulating pattern including oxygen atoms.

3. The method of claim 1, wherein the patterning the semiconductor layer into the plurality of pieces step and the forming the insulated semiconductor pillars step, collectively comprise:
forming first photoresist patterns over the semiconductor layer, the first photoresist patterns each being linear;
etching the semiconductor layer using the first photoresist patterns as an etching mask to form semiconductor lines over the semiconductor plate;
removing the first photoresist patterns from the semiconductor plate;
forming first preliminary insulating patterns between the semiconductor lines;
forming second photoresist patterns over the semiconductor lines and the first preliminary insulating patterns, the second photoresist patterns each being linear and the second photoresist patterns intersecting with the semiconductor lines and the first preliminary insulating patterns;
etching the semiconductor lines and the first preliminary insulating patterns using the second photoresist patterns as an etching mask to form the semiconductor pillars and first insulating patterns over the semiconductor plate;
removing the second photoresist patterns from the semiconductor plate; and
forming second insulating patterns between the semiconductor pillars and the first insulating patterns, the first and second insulating patterns including oxygen atoms.

4. The method of claim 1, wherein the semiconductor layer includes at least one first buried pattern, the at least one first buried pattern is formed along a straight line that connects selected pillars of the semiconductor pillars, and the first buried pattern does not include oxygen atoms and includes a different material than the semiconductor plate and the semiconductor layer, and
the patterning the semiconductor layer into the plurality of pieces step and the forming the insulated semiconductor pillars step, collectively comprise,
forming first photoresist patterns over the semiconductor layer and the at least one first buried pattern, the first photoresist patterns each being linear and intersecting with the at least one first buried pattern;
etching the semiconductor layer and the at least one first buried pattern using the first photoresist patterns as an etching mask to form semiconductor lines over the semiconductor plate, the semiconductor lines including second buried patterns divided from the at least one first buried pattern, respectively;
removing the first photoresist patterns from the semiconductor plate;
forming first preliminary insulating patterns between the semiconductor lines;
forming second photoresist patterns over the semiconductor lines and the first preliminary insulating patterns, the second photoresist patterns each being linear, at least one of the second photoresist patterns overlapping with the second buried patterns, and the second photoresist patterns being located in parallel with the second buried patterns;
etching the semiconductor lines and the first preliminary insulating patterns using the second photoresist patterns as an etching mask to form the semiconductor pillars and first insulating patterns over the semiconductor plate, the selected pillars corresponding to third buried patterns divided from the second buried patterns, respectively;
removing the second photoresist patterns from the semiconductor plate; and
forming second insulating patterns between the semiconductor pillars and the first insulating patterns, the first and second insulating patterns including oxygen atoms.

5. The method of claim 1, further comprising recrystallizing the semiconductor pillars by irradiating the semiconductor pillars with a laser using the semiconductor plate as a seed.

6. A method of forming a semiconductor device, comprising:
preparing a semiconductor plate;
forming a semiconductor layer over a semiconductor plate, the semiconductor layer including one selected from the group consisting of single-crystalline silicon, poly-crystalline silicon, amorphous silicon, gallium arsenide (GaAs), gallium nitride (GaN), gallium phosphide (GaP), indium phosphide (InP), silicon-germanium (Si—Ge), and a combination thereof;
patterning the semiconductor layer into a plurality of pieces; and
forming insulated semiconductor pillars over the semiconductor plate, the semiconductor plate including a different material than the semiconductor layer and formed of materials excluding oxygen atoms.

7. The method of claim 6, wherein the patterning the semiconductor layer into the plurality of pieces step and the forming the insulated semiconductor pillars step, collectively comprise:
forming photoresist patterns over the semiconductor layer, the photoresist patterns overlapping with the semiconductor pillars, respectively;
etching the semiconductor layer using the photoresist patterns as an etching mask to form the semiconductor pillars over the semiconductor plate;
removing the photoresist patterns from the semiconductor plate; and
forming an insulating pattern between the semiconductor pillars.

8. The method of claim 7, wherein,
the semiconductor plate includes one selected from the group consisting of single-crystalline silicon, poly-crystalline silicon, amorphous silicon, GaAs, GaN, GaP, InP, Si—Ge, and a combination thereof, and
the insulating pattern includes oxygen atoms.

9. The method of claim 6, wherein the patterning the semiconductor layer into the plurality of pieces step and the forming the insulated semiconductor pillars step, collectively comprise:
forming first photoresist patterns over the semiconductor layer, the first photoresist patterns each being linear;
etching the semiconductor layer using the first photoresist patterns as an etching mask to form semiconductor lines over the semiconductor plate;
removing the first photoresist patterns from the semiconductor plate;
forming first preliminary insulating patterns between the semiconductor lines;
forming second photoresist patterns over the semiconductor lines and the first preliminary insulating patterns, the second photoresist patterns each being linear and the second photoresist patterns intersecting with the semiconductor lines and the first preliminary insulating patterns;
etching the semiconductor lines and the first preliminary insulating patterns using the second photoresist patterns as an etching mask to form the semiconductor pillars and first insulating patterns over the semiconductor plate;
removing the second photoresist patterns from the semiconductor plate; and
forming second insulating patterns between the semiconductor pillars and the first insulating patterns.

10. The method of claim 9, wherein,
the semiconductor plate includes one selected from the group consisting of single-crystalline silicon, poly-crystalline silicon, amorphous silicon, GaAs, GaN, GaP, InP, Si—Ge, and a combination thereof, and
the first and second insulating patterns include oxygen atoms.

11. The method of claim 6, wherein the semiconductor layer includes at least one first buried pattern, and the at least one first buried pattern is formed along a straight line that connects selected pillars of the semiconductor pillars, and
the patterning the semiconductor layer into the plurality of pieces and the forming the insulated semiconductor pillars step, collectively comprise,
forming the first photoresist patterns over the semiconductor layer and the at least one first buried pattern, the first photoresist patterns each being linear and intersecting with the at least one first buried pattern;
etching the semiconductor layer and the at least one first buried pattern using the first photoresist patterns as an etching mask to form semiconductor lines, the semiconductor lines including second buried patterns divided from the at least one first buried pattern, respectively;
removing the first photoresist patterns from the semiconductor plate;
forming first preliminary insulating patterns between the semiconductor lines;
forming second photoresist patterns over the semiconductor lines and the first preliminary insulating patterns, the second photoresist patterns each being linear, at least one of the second photoresist patterns overlapping with the second buried patterns, and the second photoresist patterns being located in parallel with the second buried patterns;
etching the semiconductor lines and the first preliminary insulating patterns using the second photoresist patterns as an etching mask to form the semiconductor pillars and first insulating patterns over the semiconductor plate, the selected pillars corresponding to third buried patterns divided from the second buried patterns, respectively;
removing the second photoresist patterns from the semiconductor plate; and
forming second insulating patterns between the semiconductor pillars and the first insulating patterns.

12. The method of claim 11, wherein,
each of the semiconductor plate and the at least one first buried pattern includes one selected from the group consisting of single-crystalline silicon, poly-crystalline silicon, amorphous silicon, GaAs, GaN, GaP, InP, Si—Ge, and a combination thereof, the at least one first buried pattern includes different material from the semiconductor plate and the semiconductor layer, and
the first and second insulating patterns include oxygen atoms.

13. The method of claim 12, wherein the semiconductor layer includes at least one fourth buried pattern intersecting with the at least one first buried pattern, and
at least one of the first photoresist patterns overlaps with the at least one fourth buried pattern, the first photoresist patterns are located in parallel with the at least one fourth buried pattern, the at least one fourth buried pattern is formed as a fifth buried pattern constituting at least one of the semiconductor lines after the etching of the semiconductor layer and the at least one first buried pattern, and the fifth buried pattern is formed as sixth buried patterns underneath the second photoresist patterns after the etching of the semiconductor lines and the first preliminary insulating patterns.

14. The method of claim 13, wherein the first buried pattern has a greater width than the second photoresist patterns, and the fourth buried pattern has a greater width than the first photoresist patterns.

15. The method of claim 6, further comprising recrystallizing the semiconductor pillars by irradiating the semiconductor pillars with a laser using the semiconductor plate as a seed.

16. A method of forming a semiconductor module, comprising:
preparing a module substrate; and
forming at least one semiconductor package structure electrically connected to the module substrate,
wherein the at least one semiconductor package structure has at least one semiconductor device, and the at least one semiconductor device has at least one semiconductor cell array region on a semiconductor plate,
the at least one semiconductor cell array region is formed by,
forming a semiconductor layer over the semiconductor plate;
patterning the semiconductor layer into a plurality of pieces; and
forming insulated semiconductor pillars over the semiconductor plate, and
the semiconductor plate has a different material than the semiconductor layer, and the semiconductor plate and the semiconductor layer are formed of materials that exclude oxygen atoms.

17. The method of claim 16, wherein the patterning the semiconductor layer into the plurality of pieces step and the forming the insulated semiconductor pillars step, collectively comprise:
forming photoresist patterns over the semiconductor layer, the photoresist patterns overlapping with the semiconductor pillars, respectively;
etching the semiconductor layer using the photoresist patterns as an etching mask to form the semiconductor pillars over the semiconductor plate;
removing the photoresist patterns from the semiconductor plate; and
forming an insulating pattern between the semiconductor pillars, the insulating pattern including oxygen atoms.

18. The method of claim 16, wherein the patterning the semiconductor layer into the plurality of pieces step and the forming the insulated semiconductor pillars step, collectively comprise:
forming first photoresist patterns over the semiconductor layer, the first photoresist patterns each being linear;
etching the semiconductor layer using the first photoresist patterns as an etching mask to form semiconductor lines over the semiconductor plate;
removing the first photoresist patterns from the semiconductor plate;
forming first preliminary insulating patterns between the semiconductor lines;
forming second photoresist patterns over the semiconductor lines and the first preliminary insulating patterns, the second photoresist patterns each being linear and the second photoresist patterns intersecting with the semiconductor lines and the first preliminary insulating patterns;
etching the semiconductor lines and the first preliminary insulating patterns using the second photoresist patterns as an etching mask to form the semiconductor pillars and first insulating patterns over the semiconductor plate;
removing the second photoresist patterns from the semiconductor plate; and
forming second insulating patterns between the semiconductor pillars and the first insulating patterns, the first and second insulating patterns including oxygen atoms.

19. The method of claim 16, wherein the semiconductor layer includes at least one first buried pattern, the at least one first buried pattern is formed along a straight line that connects selected pillars of the semiconductor pillars, and the at least one first buried pattern does not include oxygen atom and includes different material from the semiconductor plate and the semiconductor layer, and
the patterning the semiconductor layer into the plurality of pieces step and the forming the insulated semiconductor pillars step, collectively comprise,
forming the first photoresist patterns over the semiconductor layer and the at least one first buried pattern, the first photoresist patterns each being linear and intersecting with the at least one first buried pattern;
etching the semiconductor layer and the at least one first buried pattern using the first photoresist patterns as an etching mask to form semiconductor lines over the semiconductor plate, the semiconductor lines including second buried patterns divided from the at least one first buried pattern, respectively;
removing the first photoresist patterns from the semiconductor plate;
forming first preliminary insulating patterns between the semiconductor lines;
forming second photoresist patterns over the semiconductor lines and the first preliminary insulating patterns, the second photoresist patterns each being linear, at least one of the second photoresist patterns overlapping with the second buried patterns, and the second photoresist patterns being located in parallel with the second buried patterns;
etching the semiconductor lines and the first preliminary insulating patterns using the second photoresist patterns as an etching mask to form the semiconductor pillars and first insulating patterns over the semiconductor plate, the selected pillars corresponding to third buried patterns divided from the second buried patterns, respectively;
removing the second photoresist patterns from the semiconductor plate; and
forming second insulating patterns between the semiconductor pillars and the first insulating patterns, the first and second insulating patterns including oxygen atoms.

20. The method of claim 16, further comprising recrystallizing the semiconductor pillars by irradiating the semiconductor pillars with a laser using the semiconductor plate as a seed.

21-22. (canceled)
